(19) United States
(12) Patent Application Publication
(10) Pub. No.: US 2019/0067178 A1
(43) Pub. Date: Feb. 28, 2019

(54) FINE PITCH AND SPACING INTERCONNECTS WITH RESERVE INTERCONNECT PORTION

(71) Applicant: QUALCOMM Incorporated, San Diego, CA (US)

(72) Inventors: Kuiwon Kang, San Diego, CA (US); Houssam Jomaa, San Diego, CA (US); Layal Rouhana, San Diego, CA (US)

(21) Appl. No.: 15/690,541

(22) Filed: Aug. 30, 2017

(51) Int. Cl. H01L 23/498; H01L 23/528; H01L 23/00; H01L 21/768

(52) U.S. Cl. CPC H01L 23/49827; H01L 23/528; H01L 24/05; H01L 2224/16237; H01L 24/81; H01L 21/768; H01L 2224/05147; H01L 24/16

(57) ABSTRACT

Some features pertain to a substrate that includes a first dielectric, a first interconnect, and a second interconnect. The first interconnect is at least partially embedded in the first dielectric layer. The first interconnect includes a first portion and a second portion. The first portion is configured to increase reliability as compared to a substrate having only a second portion of a first interconnect. The increase in reliability due at least in part to the first portion providing additional interconnect material to mitigate interconnect material lost through electromigration. A part of the second portion (of the first interconnect) is free of the first dielectric and may be configured to be coupled to another device.

### BACKGROUND

### Field of the Disclosure

Various features relate to a substrate that includes fine pitch and spacing interconnects.

### Background

Integrated circuits, integrated circuit packages and electronic devices are being continually driven to smaller form factors. The connections between such devices are correspondingly being driven to have smaller width and finer pitches to increase input/output while still maintaining the smaller form factor. However, challenges exist in achieving finer line and space interconnects.

FIG. 1A shows an example of a die and of substrate prior to coupling (i.e. prior to soldering). FIG. 1A shows an example of a substrate that includes embedded conventional interconnects. Specifically, FIG. 1A illustrates substrate 100 that includes a dielectric layer 102. FIG. 1A also illustrates a first interconnect 104a and a second interconnect 104b, embedded in the dielectric layer 102. For simplicity, FIG. 1A is discussed primarily in terms of first interconnect 104a. However, these concepts would also apply to second interconnect 104b. The top portion of the first interconnect 104a is free of dielectric layer 102, i.e. the top portion of the first interconnect 104a is not covered by the dielectric layer 102. All of the other sides of the first interconnect 104a (e.g., bottom portion, side portions) are surrounded by the dielectric layer 102. The first interconnect 104a has a thickness as measured vertically from the top of the first interconnect 104a to the bottom of the first interconnect 104a (if looking at a cross-section view, wherein the top of the first interconnect 104a is closer to the die relative to the bottom of the first interconnect 104a). For example, the first interconnect 104a thickness may be about 14-18 μm thick. As another example, the first interconnect may have a width (measured horizontally from one side to another) of about 8-12 μm. As another example, a pitch between the first interconnect 104a and the second interconnect 104b may be 16-25 μm. FIG. 1A also shows a die 110 including die interconnects 112 (e.g. a post, bump, pillar). The die interconnects 112 further include solder 114. FIG. 1B shows an example of the device of FIG. 1A after coupling of the die 110 to the substrate 100. The coupling is by way of soldering the die interconnects 112 to the first interconnect 104. After soldering (e.g., reflow of solder 114 or thermo-compression bonding), some of the solder 114 is on the first interconnect 104a. It should be noted, that after soldering there still remains first interconnect 104a material (such as copper) on the substrate (100) side of the solder joint (where the solder joint is where the die interconnect 112 couples to the first interconnect 104a).

Over time, the material of the first interconnect 104a may experience timed based consumption (e.g., copper consumption if the interconnects are made of copper) into the solder. This is due to continued slow formation of intermetallic compounds as well as electromigration. Electromigration is the gradual displacement of metal atoms in a conductor (e.g. first interconnect 104a). It occurs when the current going through the first interconnect 104a is high enough to cause the drift of metal ions. In other words, the material of the first interconnect 104a may diffuse or migrate into the solder joint such that the amount of first interconnect 104a material is diminished, i.e. the thickness of the first interconnect 104a is diminished. This displacement of metal atoms or diminishing interconnect material, may cause voiding in the joint and potentially cause an electrical open in the connection between the die 110 and the substrate 100 leading to early failure of the device. An electrical open is where there is no electrical connectivity due to an opening in the circuit.

FIG. 1C shows the device of FIG. 1B after time has elapsed, where the first interconnect 104a has electromigrated such that there is very little, to no first interconnect 104a material remaining. When there is insufficient first interconnect 104a material remaining, the electrical connection between the die 110 and the interconnect 104a becomes unreliable. Accordingly, there is a need in the industry for interconnects with very fine lines and spaces, with higher reliability that maintain ease of manufacture.

Additionally, there is an industry need for the width of the first interconnect 104a to become smaller to maintain or increase input/outputs while shrinking the overall size of the device. For similar reasons, there is also an industry need to reduce the pitch between interconnects (e.g., 104a). At the same time, there is a need for interconnects (e.g., 104a and 104b) to have sufficient thickness (due to the electromigration issue previously discussed). However, to fabricate thicker interconnect (e.g., 104) with a smaller width, a dry film used to plate/pattern the interconnect 104 must also be patterned to be narrow and tall. Moreover, if the dry film is too tall (relative to its width or the pitch of the pattern), it is difficult for light to evenly penetrate the dry film during the dry film photoresist process. This results in the interconnect (e.g., 104) being patterned with inconsistent widths which interfere with obtaining the finer/smaller interconnect widths and pitches. This is due to the inability to resolve the image of the pattern and may result in yield losses or a non-operable device. Accordingly, there is a need in the industry for interconnects with high reliability, that can be manufactured with fine/small interconnect widths and pitches.

### SUMMARY

Various features relate to a substrate that include fine pitch and spacing interconnects.

A first example provides a substrate that includes a first dielectric layer, and a first interconnect at least partially embedded in the first dielectric layer. The first interconnect includes a first portion and a second portion. The first portion and the second portion are at least partially surrounded by the first dielectric layer.

A second example provides for a method for fabricating a substrate. The method including depositing a dielectric layer and forming a first interconnect. Forming a first interconnect includes patterning a metal layer in the dielectric layer, the patterned metal layer forming a second portion of the first interconnect, and patterning another metal layer in the dielectric layer and over the second portion of the first interconnect, the another patterned metal layer forming a first portion of the first interconnect.

A third example provides a substrate comprising a first dielectric layer, and a first interconnect at least partially embedded in the first dielectric, wherein the first interconnect comprises a means for reducing electromigration (e.g., a reserve interconnect portion such as first portion 206) and a means for coupling to a die. The means for reducing electromigration and the means for coupling to a die are at least partially surrounded by the first dielectric.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a view of a substrate including conventional interconnects for connecting with a die.

FIG. 1B illustrates FIG. 1A after soldering of the die to the substrate.

FIG. 1C illustrates FIG. 1C after time has elapsed.

FIG. 2 illustrates a profile view of a substrate that includes at least partially embedded interconnects.

FIG. 3 (which comprises FIGS. 3A-3J) illustrates an example of a sequence for fabricating a substrate that includes at least partially embedded interconnects.

FIG. 4 illustrates a flow diagram of an exemplary method for fabricating a substrate that includes at least partially embedded interconnects.

FIG. 5 illustrates a package including a substrate including at least partially embedded interconnects.

FIG. 6 illustrates various electronic devices that may include the various substrates, integrated devices, integrated device packages, semiconductor devices, dies, integrated circuits, and/or packages described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams to avoid obscuring the aspects in unnecessary detail. In other instances, well-known circuits, structures and techniques may not be shown in detail in order not to obscure the aspects of the disclosure.

### Overview

Some features pertain to a substrate that includes a first dielectric, a first interconnect, and a second interconnect. The first interconnect is at least partially embedded in the first dielectric layer. In other words, the first interconnect has at least two sides (e.g., 208c and the side opposite to 208c and 206c and the side opposite to 206c) that are free of the dielectric layer. The first interconnect includes a first portion and a second portion. The first portion is coupled to the second portion and the first portion is positioned in a vertical orientation to the second portion. In other words, from a cross-section view, the second portion may be stacked over the first portion such that the first portion is in a vertical orientation to the second portion. The first portion is configured to increase reliability as compared to a substrate having only a second portion of a first interconnect. The increase in reliability due at least in part to the first portion providing additional interconnect material to mitigate interconnect material lost (e.g., through electromigration). A part of the second portion (of the first interconnect) is free of the first dielectric and may be configured to be coupled to another device. In other words, the first interconnect may be configured to be coupled to another device. In some aspects, the device is a die/integrated circuit, or a package substrate (e.g., package-on-package or POP package), or an interposer.

### Terms and Definitions

In some implementations, an interconnect is an element or component that allows or facilitates an electrical connection between two points, elements and/or components. In some implementations, an interconnect may include a trace, a via, a pad, a pillar, a redistribution metal layer, an under bump metallization (UBM) layer, solder (e.g., solder balls). In some implementations, an interconnect is an electrically conductive material that may be configured to provide an electrical path for a signal (e.g., data signal, ground signal, power signal). An interconnect may be part of a device, electronic component, substrate, interposer, printed circuit board (PCB), die, die interconnect, or circuit. In some implementations, an interconnect may include more than one element or component.

A trace is a form of an interconnect that provides an electrical path along a horizontal or near horizontal direction in an integrated device. In some implementations, a trace may be formed in a substrate or may be formed on the substrate. In some implementations, a trace that is formed in the substrate is an embedded trace. An embedded trace includes the case where at least two sides of the trace are covered by the substrate (or a dielectric of the substrate) and any remaining sides of the trace are not covered by the substrate (or dielectric of the substrate). However, a trace need not be an embedded trace, e.g., a trace may be formed on or over the substrate. A trace may traverse dielectric material.

A via is a form of an interconnect that provides an electrical path along a vertical or near vertical direction in an integrated device. In some implementations, a via may be formed in a substrate (e.g., through substrate via). In some implementations, a via may be formed in an encapsulation layer (e.g., mold). In some implementations, a via may have vertical walls, or may have tapered or sloped walls or other orientations.

A pad is a form of an interconnect that provides an electrical path in an integrated device. In some implementations, a pad is an element or component that provides a coupling interface for an interconnect made of a different material. For example, a pad may be configured to provide an interface for a solder (e.g., solder ball).

The term “embedded”, as used throughout the present disclosure, includes the case where at least two sides of an object A are covered by object B or material B, and any remaining sides of object A are not covered by object B or material B.

The term “pitch” may be defined as the distance between the mid-points of two objects respectively. For example, pitch may be the distance from the mid-point of interconnect A to the mid-point of interconnect B.

The term “width” may be defined as a lateral or horizontal measurement of an object when the object is viewed in a cross-section view. For example, the width of an interconnect (e.g., 204) is the lateral or horizontal measurement of the interconnect from a first sidewall (or first side) to its second sidewall (or second side).

The term “thickness” may be defined as a vertical measurement of an object. In other words, thickness may be defined as the measurement from the bottom to the top of an object.

### Exemplary Substrate Comprising Embedded Interconnects

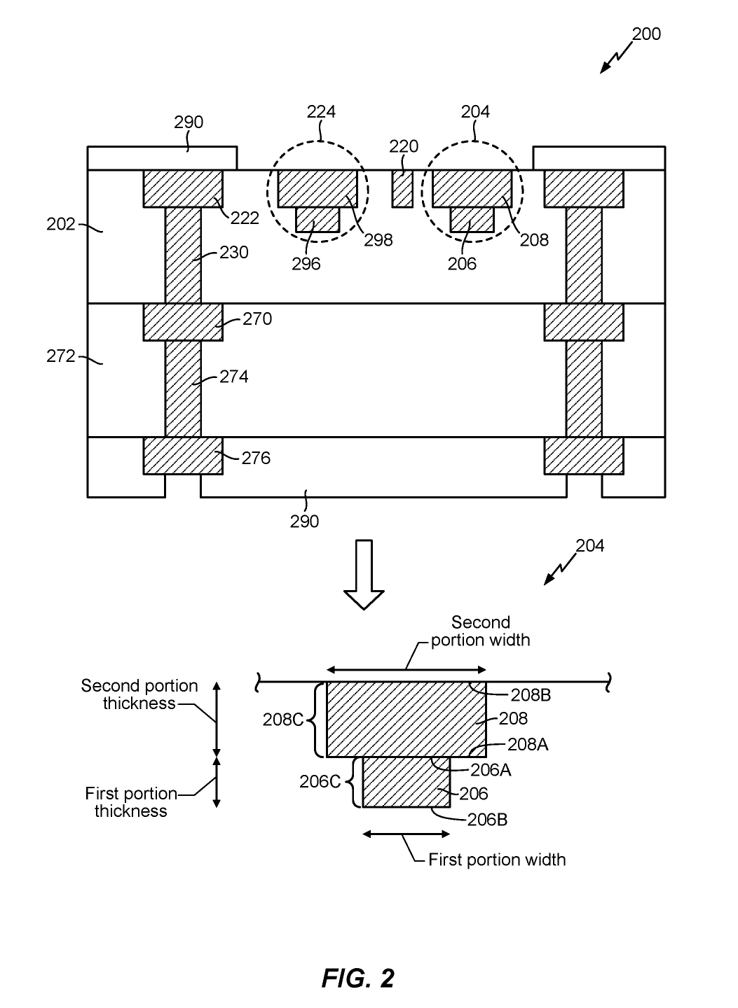

FIG. 2 illustrates an example of a substrate that includes a first interconnect comprising a first portion (i.e. a reserve portion) and a second portion. Specifically, FIG. 2 illustrates a substrate 200 that includes a first dielectric layer 202. The first dielectric layer 202 be a single layer or multiple layers. The first dielectric layer 202 may comprise one material or multiple materials. The dielectric material may include a pre-preg material (i.e. pre-impregnanted material). In one aspect, the substrate 200 may be a package substrate, an interposer, or an embedded trace substrate.

The substrate 200 also includes first interconnect 204, where the first interconnect 204 includes a first portion 206 (e.g., means for reducing electromigration) and a second portion 208 (e.g., means for coupling to a die or other devices or structures) comprising conductive material. The first portion 206 includes a first face 206A and a second face 206B. The second portion 208 includes a third face 208A and a fourth face 208B. The first portion 206 includes at least one sidewall 206C, the second portion 208 includes at least one sidewall 208C. The first portion 206 includes a first portion width (e.g., length of 206A, or 206B) and the second portion 208 includes a second portion width (e.g., length of 208A or 208B). The width of the first portion width and the second portion width may be defined as a lateral or horizontal measurement (e.g., when viewed in cross-section view) taken from a first sidewall (e.g., 206C or 208C) of the portion to a second sidewall (not labeled) of the portion. The first portion width (e.g., length of 206A or 206B) may be different than or equal to the second portion width (e.g., length of 208A or 208B).

The first portion 206 includes a first portion thickness and the second portion 208 includes a second portion thickness. The thickness of the first portion thickness and second portion thickness may be defined as a vertical measurement (e.g., when viewed in cross-section view). For example, the first portion thickness may be measured by the vertical length from first face 206A to second face 206B or by the vertical length of 206C. As another example, the second portion thickness may be measured by the vertical length from third face 208A to fourth face 208B or by the vertical length of 208C. The first portion thickness may be different than or equal to the second portion thickness. The first interconnect 204 has a first interconnect thickness comprising a first portion thickness of the first portion 206 added to a second portion thickness of the second portion 208.

The substrate 200 also includes second interconnect 224, where the second interconnect 224 includes a first portion 296 and a second portion 298. There may be a plurality of the first interconnect 204 and the second interconnect 224. In one aspect, the first interconnect 204 may form a bump pad or solder joint. In another aspect, the second interconnect 224 may form a bump pad or solder joint. The first interconnect 204 and/or the second interconnect 224 may be configured to couple to other components. For example, the first interconnect 204 and/or the second interconnect 224 may be coupled to another interconnect from another device (not shown) such as a solder ball or pillars. In another example, the first interconnect 204 and/or the second interconnect 224 may be coupled to another device not shown, such as another interconnect, a solder ball, a package substrate, an interposer, an integrated die, and a printed circuit board.

The substrate 200 also includes a third interconnect 220. In one aspect, third interconnect 220 may be a fine line or trace. The third interconnect 220 (e.g., trace) has a thin or narrow width as compared to the width of the first and second interconnect (204, 224). In one aspect, the third interconnect 220 may have a third interconnect width of 3-10 um. The width of the third interconnect 220 may be defined as a lateral or horizontal measurement (e.g., when viewed in cross-section view) taken from a first side of third interconnect 220 to a second side of third interconnect 220. There may be a plurality of the third interconnect 220.

The substrate 200 also includes a fourth interconnect 222. In one aspect, fourth interconnect 222 may be a pad configured to electrically couple to another interconnect such as a via (e.g., a fifth interconnect 230/first substrate via). There may be a plurality of fourth interconnect 222.

The substrate 200 may also include a fifth interconnect 230. In one aspect, fifth interconnect 230 may be a first through substrate via that extends vertically, at least partially through the first dielectric layer 202. The fifth interconnect 230 (e.g., through substrate via) may have a different shape than what is shown. For example, the fifth interconnect 230 may have sloped or tapered walls rather than vertical walls. Other shapes are contemplated within this disclosure. There may be a plurality of fifth interconnect 230. The fifth interconnect 230 may be configured to electrically couple to another component (e.g., 222, 270).

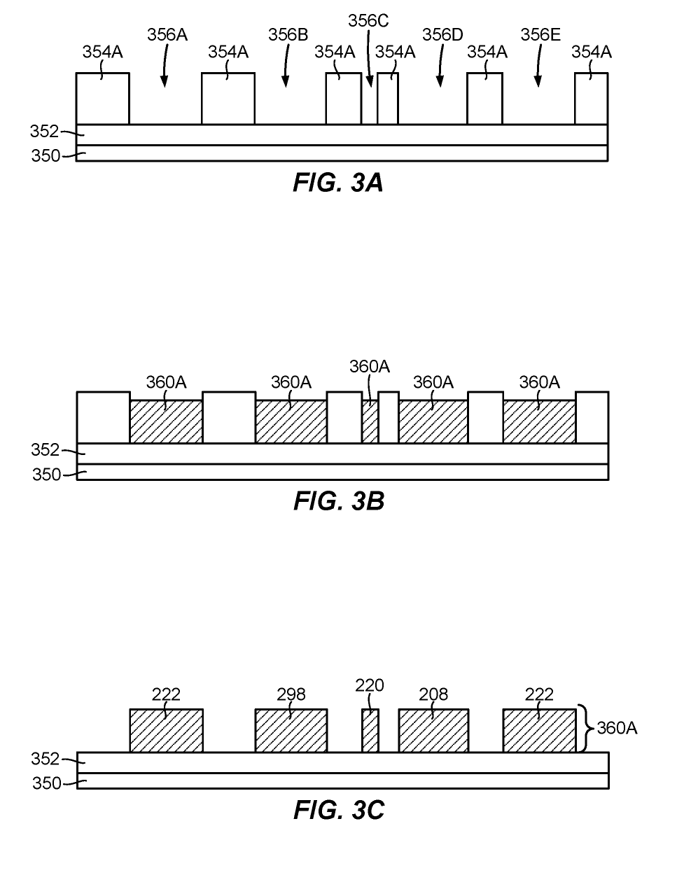

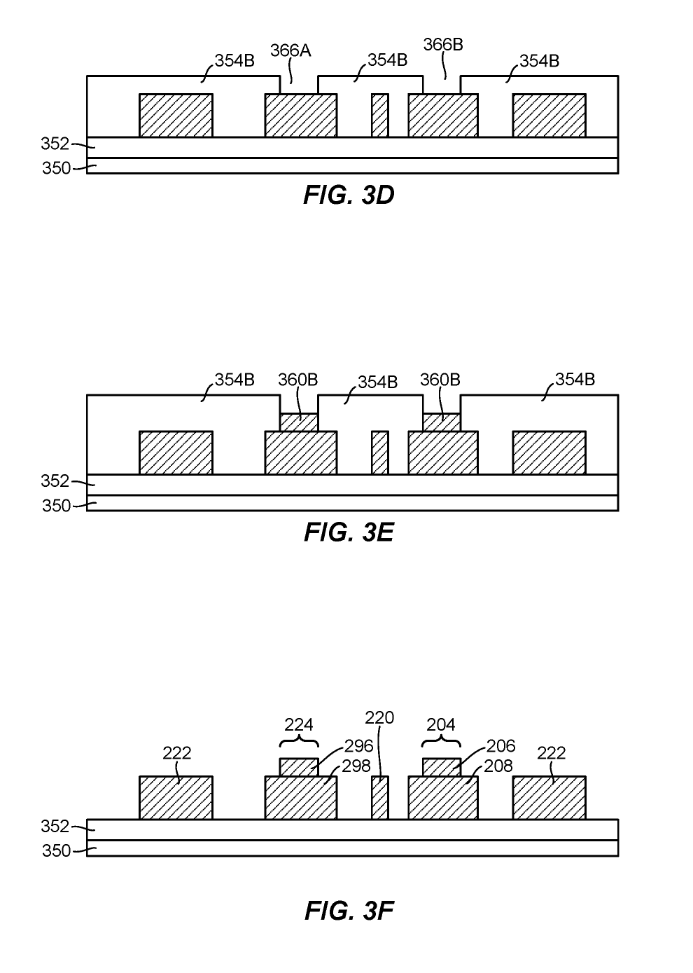

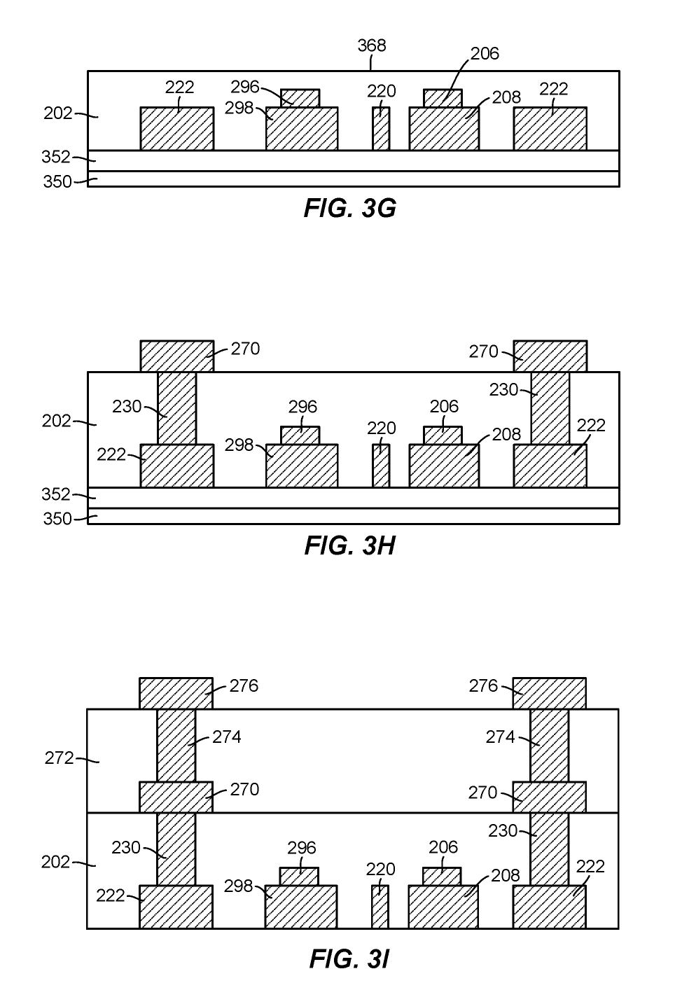

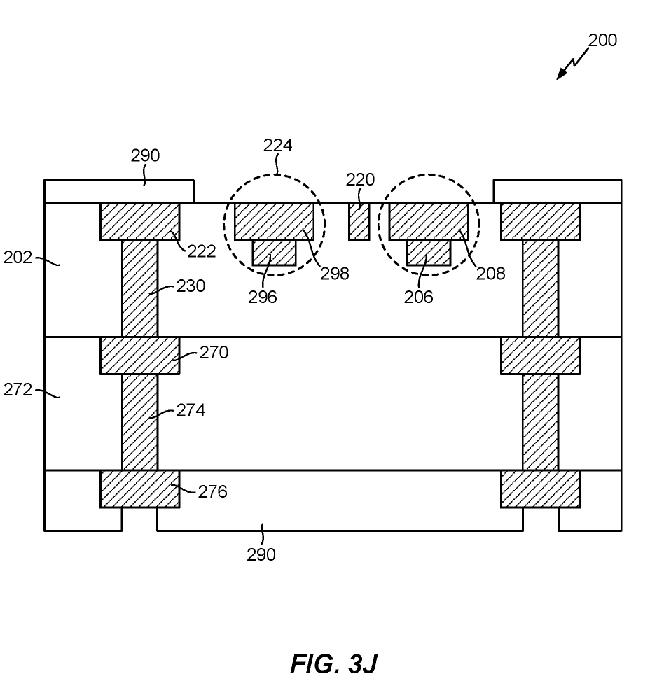

The substrate 200 may also include a sixth interconnect 270 or a plurality of sixth interconnects (270). The sixth interconnect may comprise a pad, or a trace. The sixth interconnect 270 may be placed on (or over) a surface of the first dielectric layer 202 (also see FIG. 3H where 270 is over the first dielectric layer 202). The sixth interconnect 270 may be configured to electrically couple to another component (e.g., 230, 274).

The substrate 200 may also include a seventh interconnect 274 or a plurality of seventh interconnects 274. The seventh interconnect may comprise a second through substrate via that extends through a second dielectric layer 272. FIG. 2 is exemplary, and the seventh interconnect 274 (e.g., through substrate via) may have a different shape than what is shown. For example, the seventh interconnect 274 may have sloped or tapered walls rather than vertical walls. Other shapes are contemplated within this disclosure. The seventh interconnect may be configured to electrically couple to another component (e.g., 270 or 276).

The substrate 200 may also include an eighth interconnect 276 or a plurality of eighth interconnects 276. The eighth interconnect may comprise a pad or a trace or a bump pad as examples. The eighth interconnect may be placed on (or over) a surface of the second dielectric 272. The eighth interconnect may be configured to electrically couple to another component (e.g., seventh interconnect 274, or another component not show such as a solder ball or other type of interconnect).

The interconnects (first 204, second 224, third 220, fourth 222, fifth 230, sixth 270, seventh 274, eighth 276) are made of conductive material (e.g., copper, metal etc.). The material may be a single material or a composite material (e.g., CuT etc.).

The first portion 206 and second portion 208 are coupled together via the first face 206A and third face 208A. The fourth face 208B of the second portion may be configured to couple to another device. In an aspect, the fourth face 208B may be configured to couple to a die/integrated circuit (not shown), a substrate (not shown), or a package (not shown). The fourth face 208B may be configured to couple to another interconnect (not shown) such as a solder ball, a ball, a pillar, post etc. That is, the second portion 208 (e.g., means for coupling to a die) may be configured to couple to another interconnect (e.g., solder ball, ball, pillar, post, etc.) or to a die/integrated circuit, a substrate, or a package.

The first interconnect 204 and the second interconnect 224 are embedded in the first dielectric layer 202, that is, first and second interconnects (204 and 224 respectively) are at least partially surrounded by the first dielectric layer 202. In one aspect of the first interconnect 204, the at least one sidewall 206C of the first portion and the at least one sidewall 208C of the second portion may be surrounded by first dielectric layer 202. In another aspect, second face 206B of the first portion may be surrounded by first dielectric layer 202. In another aspect, first face 206A of the first portion may be partially surrounded by dielectric 20, and in another aspect, first face 206A of the first portion may be free of the first dielectric layer 202 (for example, where the entire first face 206A is directly coupled to the third face 208A of the second portion. In one aspect, third face 208A of the second portion may be at least partially surrounded by first dielectric layer 202 (for example, where the third face 208A has a greater surface area than the first face 206A), and in another aspect, third face 208A may be free of the first dielectric layer 202 (for example, where the third face 208A has a greater or equal surface area than the first face 206A). In another aspect, the fourth face 208B may be free of dielectric so that the fourth face 208B may be configured to electrically couple to another electronic device. In another aspect, the first and second interconnects (204, 224 respectively) may be configured as embedded traces within substrate 200, where substrate 200 may be an embedded trace substrate.

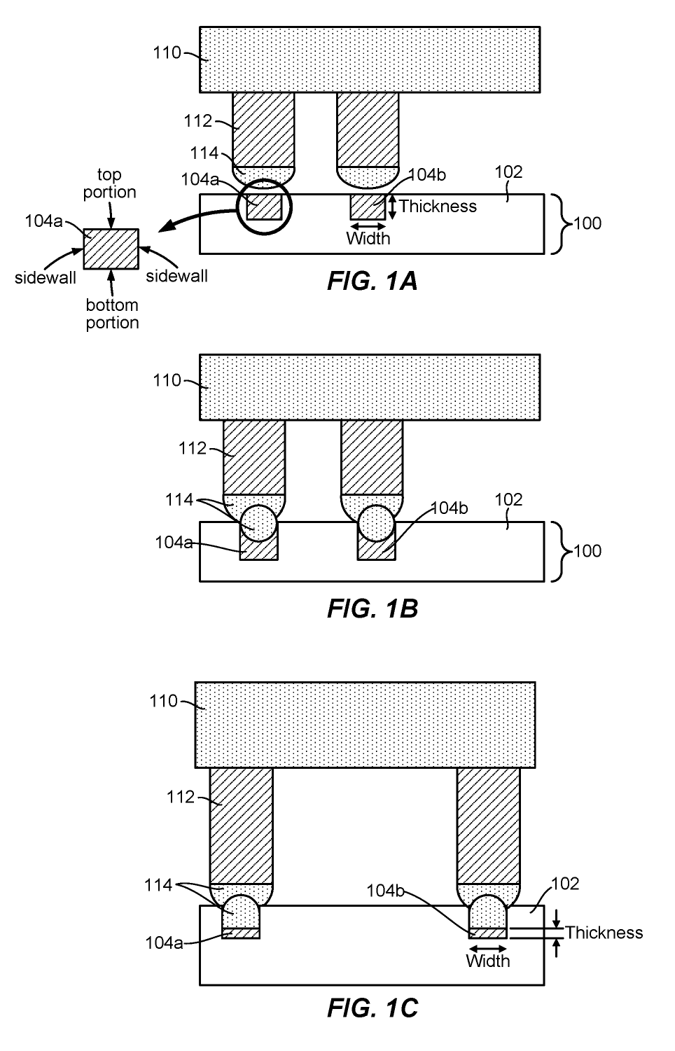

As exemplified in FIG. 2, an interconnect (e.g., first interconnect 204, second interconnect 224) having additional interconnect material (e.g., reserve material such as first portion 206) can be achieved while allowing for fine/smaller interconnect widths. In one aspect, the first portion width (e.g., length of first face 206A or second face 206B) is about 5-10 μm, and the second portion width (e.g., length of third face 208A or fourth face 208B) is about 15-30 μm. In another aspect, the first portion thickness is 5-20 μm, and the second portion thickness is about 5-10 μm. In another aspect, the pitch between a third interconnect 220 and another third interconnect such as 220 (not shown but could be located next to third interconnect 220) 220 is about 5-10 μm. In an aspect, the first portion 206 (e.g., a first means for reducing electromigration) is configured to increase reliability and reduce electromigration as compared to a substrate having only a second portion (e.g., 104 of FIG. 1), the increase in reliability due at least in part to the first portion 206 providing additional interconnect material to mitigate interconnect material lost through electromigration. A process for fabricating the device of FIG. 2 will be discussed later, the process allows for example, an aspect ratio of about 1:1.5 or less between the thickness of the interconnect (e.g., first interconnect 204, second interconnect 206) and the thickness of the dry film. This process enables a fine/small interconnect width (e.g., second portion width) while still having the additional interconnect material.

It is important to note that although FIG. 2 describes a device with three layers, where first, second, third, and fourth interconnects (i.e. 206/208, 224, 220 and 222) may comprise a first metal layer, the sixth interconnect 270 may comprise a second metal layer, and the eighth interconnect 276 may comprise a third metal layer, this disclosure is not so limited. Moreover, although FIG. 2 describes a device with two dielectric layers (e.g., first dielectric layer 202 and second dielectric layer 272), this disclosure is not so limited. For example, this disclosure also includes an aspect where the substrate 200 has only a first dielectric layer (e.g., 202) and a first metal layer (e.g., 206/208, 224, 222). This disclosure also includes an aspect similar to what is shown in FIG. 2 but where the substrate 200 has additional stacks of dielectric layers and metal layers.

### Exemplary Substrate Comprising Embedded Interconnects of Different Sizes and Shapes

FIG. 2 illustrates a first portion 206 and second portion 208 as having different sizes. FIG. 2 illustrates a first portion width (of the first portion 206, e.g., width of first face 206A, or second face 206B) that is less than the second portion width (of the second portion 208, e.g., width of third face 208A or fourth face 208B). Such a design implementation of fabricating first portion 206 with a smaller width than the second portion 208 may have some benefits since the smaller first portion 206 can more easily be aligned over second portion 208. However, the disclosure need not be so limited. In another aspect, the first portion width (of the first portion 206) is greater than or equal to the second portion width (of the second portion 208). Moreover, the embedded interconnects including first interconnect 204, second interconnect 224, third interconnect 220, and fourth interconnect 222 may have different sizes (i.e. widths) from each other. In one aspect, the third interconnect 220 may have a smaller width than the first interconnect 204, and the first interconnect 204 may have a larger thickness than the third interconnect 220.

In another aspect, first portion 206 may have a first portion shape, and the second portion 208 may have a second portion shape. FIG. 2 shows the first portion shape and the second portion shape (of 206 and 208 respectively) are different from each other. However, the shapes shown in FIG. 2 of first portion 206 and second portion 208 need not be so limited. The first portion shape and second portion shape (of 206 and 208 respectively) may be the same. In another aspect, the first portion shape and second portion shape (of 206 and 208 respectively) may be different than what is shown in FIG. 2. For example, the first portion 206 and, or the second portion 208 may have sidewalls that are more rounded or circular. Alternatively one of the first portion shape or second portion shape may be rounded while the remaining first portion 206 or second portion 208 may not be rounded (i.e. more angular).

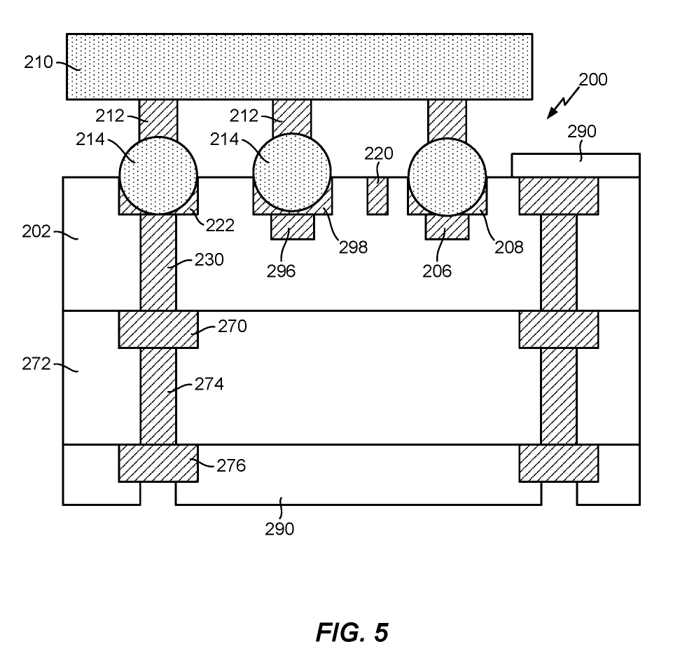

Solder resist 290 may be selectively placed on the substrate 200. The solder resist 290 is configured to prepare the substrate 200 so that later, it can be attached or coupled to another device (e.g., 210 and see discussion for FIG. 5) such as a die, an integrated circuit, a substrate, or another package as examples. The solder resist 290 protects areas of the substrate 200 from solder on the device to be attached.

Exemplary Sequence for Manufacturing a Substrate that Includes Embedded Interconnects

In some implementations, manufacturing a substrate that includes embedded interconnects includes several processes. FIG. 3 (which includes FIGS. 3A-3J) illustrates an exemplary sequence for manufacturing a substrate that includes embedded interconnects. In some implementations, the sequence of FIGS. 3A-3L may be used to manufacture the substrate of FIG. 2 and/or other substrates described in the present disclosure. FIG. 3A-3J will now be described in the context of manufacturing the substrate that includes embedded interconnects of FIG. 2.

It should be noted that the sequence of FIG. 3A-3J may combine one or more stages to simplify and/or clarify the sequence. In some implementations, the order of the processes may be changed or modified.

FIG. 3A illustrates a carrier 350 that is provided. The carrier 350 may be provided by a supplier or manufactured. The carrier 350 may be a dielectric layer (e.g., cured dielectric layer). A seed layer 352 may be provided over the carrier 350. Seed layer 352 may include one or more layers. A photo resist layer 354A (e.g., dry film resist) is provided over the seed layer 352. The photo resist layer 354A may be selectively etched or developed to remove some of the photo resist layer 354A. Etching or patterning of the photo resist layer 354A results in cavities 356A-356E. The size of the cavities 356A-356E and the spacing between the cavities 356A-356E are controlled by the width (measured from first side to second side in a horizontal direction), and thickness (measured from top to bottom of 354A in a vertical direction) of the photo resist layer 354A. The size of the cavities 356A-356E and the spacing between the cavities 356A-356E have a direct correlation with the second portion width (e.g., 208) of the first and second interconnects 204, 224.

In one aspect, the photo resist layer 354A is patterned with the following widths 4-10 μm. In another aspect, the patterned photo resist layer 354A has a thickness such that the aspect ratio of the thickness of the first interconnect (e.g., 204, 224) to the thickness of the photo resist is less than 1:1.5. In another aspect, the patterned photo resist layer 354A has a thickness of 7-15 μm.

FIG. 3B illustrates a first metal layer 360A provided on the carrier 350. As will be discussed later (see discussion regarding FIG. 3C), the first metal layer 360A forms a portion of the first and second interconnects, and the third and fourth interconnects (i.e. 208, 298, 220, and 222). The first metal layer 360a may be deposited in the cavities 356A-356E. The first metal layer 360A may be a metal plating layer. The first metal layer 360A may comprise a single metal material, or a composite metal material. The first metal layer 360A may comprise one layers or more. The first metal layer 360A is a conductive material, configured for electrical coupling.

FIG. 3C illustrates the structure after photo resist layer 354A is removed. Different implementations may use different processes for removing the photo resist layer 354A. Removing the photo resist layer 354A (such as with an alkaline bath) leaves the first metal layer 360A on the carrier 350. The remaining first metal layer 360A forms or comprises all or part of the following: at least the second portion 208 of the first interconnect 204, at least the second portion 298 of the second interconnect 224, the third interconnect 220, the fourth interconnect 222. Each of these portions and interconnects are electrically conductive and may be configured for electrical coupling.

FIG. 3D illustrates a photo resist layer 354B provided over the carrier and over all or parts of the first metal layer 360A (i.e. where the first metal layer comprises at least portions of first interconnect 204, second interconnect 224, third interconnect 220, and fourth interconnect 222). In one aspect, the photo resist layer 354B is provided to form first portion (e.g., 206) of first interconnect 204 and first portion 296 of second interconnect 224. In one aspect, the photo resist layer 354B covers a first sidewall (e.g., 208C of FIG. 2) and a second sidewall of the second portion 208, leaving at least a portion of third face 208A of second portion 208 free of photo resist layer 354B. In another aspect, photo resist layer 354B covers the top portions of third interconnect 220, and fourth interconnect 222. In other words, in an aspect, the photo resist layer 354B covers all interconnects where additional or reserve interconnect material is not desired. Furthermore, in the same aspect, photo resist layer 354B does not cover interconnects or areas of interconnects where additional or reserve interconnect material (e.g., first portion 206) is desired.

As discussed with respect to FIG. 3A, the photo resist layer 354B of FIG. 3D is patterned. Etching or patterning of the photo resist layer 354B results in cavities 366A-B. The size of the cavities 366A366B and the spacing between the cavities 366A-366B are controlled by the width, and thickness of the photo resist layer 354B. The size of the cavities 366A-366B and the spacing between the cavities 366A-366B have a direct correlation with the first portion width (e.g., width of 206A, or 206B) of the first and second interconnects 204, 224.

FIG. 3E illustrates another first metal layer 360B provided on the carrier 350. The first metal layer 360B may be deposited in the cavities 366A-B. The first metal layer 360B may be a metal plating layer. The first metal layer 360B may comprise a single metal material, or a composite metal material. The first metal layer 360B may comprise one layers or more. First metal layer 360B is a conductive material and is configured for electrical coupling.

FIG. 3F illustrates the structure after photo resist layer 354B is removed. Removing the photo resist layer 354B leaves (the another) first metal layer 360B on the carrier 350. The remaining first metal layer 360B forms or comprises all or part of the following: at least the first portion 206 of the first interconnect 204, at least the first portion 296 of the second interconnect 224. In other words, FIG. 3F illustrates the structure where first interconnect 204 and second interconnect 224 are formed.

FIG. 3G illustrates providing a first dielectric layer 202 over the carrier 350. The first dielectric layer 202 may comprise a pre-preg layer. Examples of first dielectric are epoxy dielectric, resin coated CU, glass filled dielectric etc. Depositing the first dielectric layer 202 may include pressing the first dielectric layer 202 with a foil, such as a copper foil (not shown). The first dielectric layer 202 covers some or all of the first metal layer 360A and 360B (e.g., first interconnect 204, second interconnect 224, third interconnect 220, and fourth interconnect 222). In one aspect, the first dielectric layer 202 covers at least a part of the first portion 206, including the second face 206B, part of the first face 206A and the sidewalls 206C (see FIG. 2 for 206A, 206B and 206C). In another aspect, the first dielectric layer 202 may not cover any part of the first face 206A (e.g., when the first face 206A width is equal to or less than the third face 208A width). In another aspect, the first dielectric layer 202 covers at least a part of the second portion 208, including part of the third face 208A and the sidewalls 208C (see FIG. 2 for 208A and 208C). In another aspect, the first dielectric layer 202 may not cover any part of the third face 208A of the second portion 208. In another aspect, the first dielectric layer 202 may not cover fourth face 208B at all, so that 208B may be electrically coupled to another interconnect, die, package substrate, or interposer. In another aspect, the dielectric layer 202 will not cover the first metal layer 360A and 360B where the dielectric layer 202 is later removed. For example, see FIG. 3H where dielectric 202 is removed from a portion of fourth interconnect 222 to electrically couple fifth interconnect 230.

Where a multi-metal layered/multi-dielectric layered device is desired, additional manufacturing may occur as follows.

FIG. 3H illustrates providing fifth interconnects 230 in the first dielectric layer 302. The fifth interconnects 230 may be first through substrate vias formed for example, by drilling via holes in the first dielectric layer 202 and filling the via holes with fifth interconnect material (i.e. an electrically conductive material such as metal). Furthermore, FIG. 3H illustrates a sixth interconnect 270 is patterned over the first dielectric layer 202. In some aspects, the sixth interconnect 270 is patterned over the fifth interconnect 230 (e.g., first through substrate via) such that fourth interconnect 222 is configured to electrically couple to the sixth interconnect 270 through the fifth interconnect 230. The patterning of the sixth interconnect 270 may be done by way of using a photo resist process and electroplating process as already discussed. The sixth interconnect 270 may comprise a second metal layer. The second metal layer is a conductive material and may be configured for electrical coupling.

FIG. 3I illustrates forming a second dielectric 272 and FIG. 3I illustrates forming seventh interconnect 274 with a conductive material. The seventh interconnect 274 is formed in the second dielectric 272. In one aspect, the seventh interconnect 274 may be a second through substrate via. The second through substrate via is configured to be electrically conductive. Furthermore, FIG. 3I illustrates forming or patterning eighth interconnect 276 over the second dielectric 272. The eighth interconnect 276 comprises a conductive material. The eighth interconnect 276 may comprise a third metal layer. The third metal layer is a conductive material and may be configured for electrical coupling.

FIG. 3J illustrates separation or removal of the carrier 350 and removal of the seed layer 352. The seed layer 352 may be removed by seed etching. Optionally, solder resist 290 may be selectively placed on the substrate 200. The solder resist 290 prepares the substrate 200 so that later, it can be attached or coupled to another device (e.g., 210 and see discussion for FIG. 5) such as a die, an integrated circuit, a substrate, or another package as examples. The solder resist 290 protects areas of the substrate 200 from solder on the device to be attached.

It is important to note that although FIG. 3 describes a device with two dielectric layers (e.g., 202 and 272) and three metal layers (e.g., 206/208, 224, 222 and 270 and 276), this disclosure is not so limited. Certain sequences may be omitted to form less layers, or certain sequences may be repeated to form additional stacked layers of dielectric and metal layers.

Exemplary Flow Diagram of a Method for Manufacturing a Substrate that Includes Embedded Interconnects

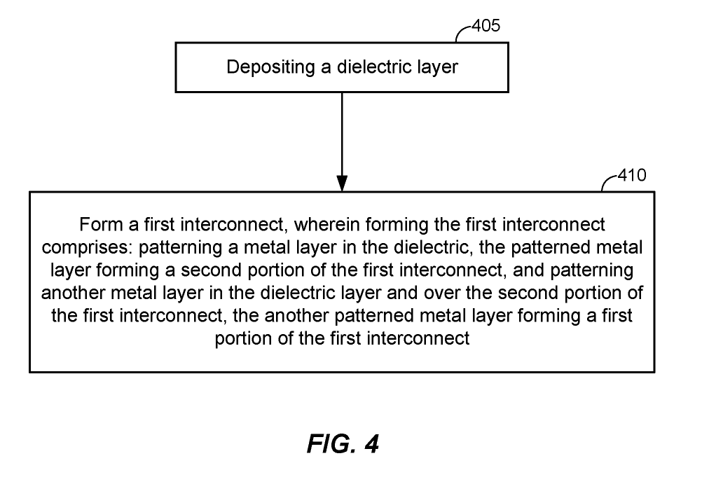

FIG. 4 illustrates an exemplary flow diagram of a high level method for manufacturing a substrate (e.g., package substrate) that includes embedded interconnects. It should be noted that for the purpose of clarity and simplification, the flow diagram of FIG. 4 does not necessarily include all the steps of manufacturing a substrate that includes one or more embedded interconnects. Moreover, in some instances, several steps may have been combined into a single step to simplify the description of the sequences.

As shown in FIG. 4, the method includes depositing (at step 405) a dielectric layer. Different implementations may deposit the dielectric layer differently. FIG. 3G illustrates an example of depositing a dielectric layer such as first dielectric layer 202.

The method (at step 410) forms a first interconnect, wherein forming the first interconnect comprises patterning a metal layer in the dielectric, the patterned metal layer forming a second portion of the first interconnect, and patterning another metal layer in the dielectric layer and over the second portion of the first interconnect, the another patterned metal layer forming a first portion of the first interconnect. FIG. 3A-FIG. 3F illustrates forming the first interconnect 204 in the dielectric. FIG. 3B illustrates patterning a metal layer (e.g., first metal layer 360A) and FIG. 3C illustrates the patterned metal layer (e.g., 360A) forms the second portion 208 of the first interconnect (e.g., 204). FIG. 3E illustrates patterning another metal layer (e.g., first metal layer 360B) over the second portion (208). FIG. 3F illustrates the another patterned metal layer (e.g., first metal layer 360B) forms the first portion (206) of the first interconnect 204.

### Exemplary Package Including a Package Substrate Comprising Embedded Interconnects

FIG. 5 is similar to FIG. 2, however FIG. 5 illustrates the package 200 of FIG. 2 when coupled to another device 210. Device 210 may be a die/integrated circuit, or a package substrate (e.g., where the substrate 200 coupled to a package substrate would form a package-on-package or POP package), or an interposer. Device 210 may include a first device interconnect 212 and a second device interconnect 214. The first and second device interconnect 212 and 214 respectively comprise conductive material and are configured to couple the device 210 to the package 200, for example by way of first interconnect 204 and/or for example by way of second portion 208 of first interconnect 204.

### Exemplary Electronic Devices

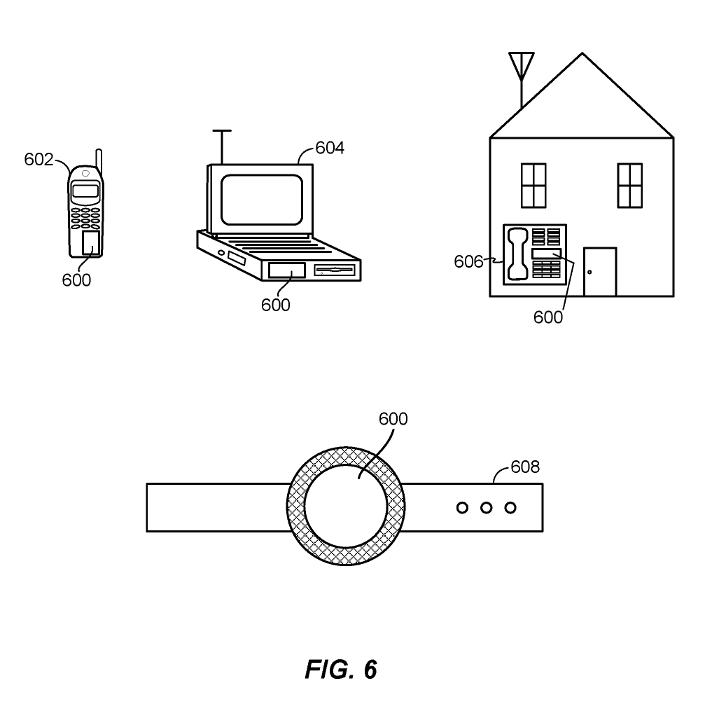

FIG. 6 illustrates various electronic devices that may be integrated with any of the aforementioned substrate, integrated device, semiconductor device, integrated circuit, die, interposer, or package. For example, a mobile phone device 602, a laptop computer device 604, a fixed location terminal device 606, a wearable device 608 may include an integrated device 600 as described herein. The integrated device 600 may be, for example, any of the substrate, integrated circuits, dies, integrated devices, integrated device packages, integrated circuit devices, device packages, integrated circuit (IC) packages, package-on-package devices described herein. The devices 602, 604, 606, 608 illustrated in FIG. 6 are merely exemplary. Other electronic devices may also feature the integrated device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watch, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2 through 5, and/or 6 may be rearranged and/or combined into a single component, process, feature or function or embodied in several components, processes, or functions. Additional elements, components, processes, and/or functions may also be added without departing from the disclosure. It should also be noted that FIGS. 2 through 5, and/or 6 and its corresponding description in the present disclosure is not limited to substrates. In some implementations, FIGS. 2 through 5, and/or 6 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “traverse” as used herein, means to go across and includes going all the way across an object or partially across an object.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A substrate comprising:
a first dielectric layer; and
a first interconnect at least partially embedded in the first dielectric layer, wherein the first interconnect comprises a first portion and a second portion, the first portion and the second portion are at least partially surrounded by the first dielectric layer.

2. The substrate of claim 1, wherein the first interconnect comprises a first interconnect thickness including a first portion thickness of the first portion and a second portion thickness of the second portion, the first interconnect thickness is about 10-30 μm.

3. The substrate of claim 1, wherein the first portion includes a first portion width and the second portion includes a second portion width, wherein the first portion width is less than the second portion width.

4. The substrate of claim 3, wherein the first portion width is about 5-10 μm.

5. The substrate of claim 3, wherein the second portion width is about 15-30 μm.

6. The substrate of claim 1, wherein the first portion includes a first portion width and the second portion includes a second portion width, wherein the first portion width is greater than or equal to the second portion width.

7. The substrate of claim 1, wherein the first portion includes a first portion shape and the second portion includes a second portion shape, the first portion shape is different than the second portion shape.

8. The substrate of claim 1, wherein the first portion is coupled to the second portion and the first portion is positioned in a vertical orientation to the second portion.

9. The substrate of claim 8, wherein the first portion includes a first face, the second portion includes a second face, wherein the first portion and the second portion are coupled together via the first face and the second face respectively.

10. The substrate of claim 1, wherein the second portion is configured to couple to a device selected from the group consisting of another interconnect, a solder ball, a package substrate, an interposer, an integrated die, and a printed circuit board.

11. The substrate of claim 1, wherein the substrate is an embedded trace substrate.

12. The substrate of claim 1, wherein the first portion includes a first portion sidewall, and the second portion includes a second portion sidewall, the first portion sidewall and the second portion sidewall are at least partially surrounded by the first dielectric layer.

13. The substrate of claim 1, further comprising:
a plurality of third interconnects, wherein a pitch between a first of the plurality of third interconnects and a second of the plurality of third interconnects is about 5-10 μm.

14. The substrate of claim 13, wherein the plurality of third interconnects comprise a trace.

15. The substrate of claim 1, wherein the first interconnect comprises a bump pad that includes copper.

16. The substrate of claim 1, wherein the first portion is configured to increase reliability by providing additional interconnect material.

17. The substrate of claim 1, wherein the substrate is incorporated into a device selected from a group consisting of a music player, a video player, an entertainment unit, a navigation device, a communications device, a mobile device, a mobile phone, a smart phone, a personal digital assistant, a fixed location terminal or server, a tablet computer, and a laptop computer.

18. A method for fabricating a substrate comprising:
depositing a dielectric layer; and
forming a first interconnect, wherein forming the first interconnect comprises:
patterning a metal layer in the dielectric layer, the metal layer forming a second portion of the first interconnect; and
patterning another metal layer in the dielectric layer and over the second portion of the first interconnect, the another metal layer forming a first portion of the first interconnect.

19. The method of claim 18, wherein patterning the metal layer further comprises:
patterning a first photo resist layer to form a plurality of first cavities;
depositing a first metal layer in the plurality of first cavities;
removing the first photo resist layer, wherein removing the first photo resist layer leaves the second portion of the first interconnect.

20. The method of claim 19, wherein patterning the another metal layer further comprises:
patterning a second photo resist to partially cover a first sidewall and second sidewall of the second portion of the first interconnect, wherein patterning the second photo resist layer further comprises forming a plurality of second cavities over the second portion of the first interconnect;
depositing another first metal layer in the plurality of second cavities;
removing the second photo resist layer, wherein removing the second photo resist layer leaves the first portion of the first interconnect over the second portion of the first interconnect.

21. The method of claim 20, wherein the first metal layer and the another first metal layer may be the same or different materials.

22. The method of claim 21, wherein providing the second photo resist includes patterning the second photo resist over components selected from the group consisting of an embedded trace, and an embedded pad.

23. A substrate comprising:
a first dielectric layer; and
a first interconnect at least partially embedded in the first dielectric layer, wherein the first interconnect comprises means for reducing electromigration and means for coupling to a die, the means for reducing electromigration and the means for coupling to the die are at least partially surrounded by the first dielectric layer.

24. The substrate of claim 23, wherein the means for reducing electromigration includes a first portion of the first interconnect, the first portion of the first interconnect configured to act as a reservoir of interconnect material.

25. The substrate of claim 24, further comprising:
wherein the first portion includes a first portion width;
wherein the means for coupling to the die comprises a second portion of the first interconnect, the second portion includes a second portion width; and
wherein the first portion width is less than the second portion width.

26. The substrate of claim 23, wherein the means for coupling to the die comprises a first portion of the first interconnect, the first portion of the first interconnect configured to couple to a device selected from the group consisting of a second interconnect, a solder ball, a package substrate, an interposer, an integrated circuit, and a printed circuit board.

27. The substrate of claim 23, wherein the first interconnect includes a first interconnect thickness of about 10-30 μm.
